(19) United States
(12) Patent Application Publication
(10) Pub. No.: US 2024/0316915 A1
(43) Pub. Date: Sep. 26, 2024

(54) PATTERN DESIGN METHOD, TEMPLATE MANUFACTURING METHOD, AND PATTERN DESIGN APPARATUS

(71) Applicant: Kioxia Corporation, Tokyo (JP)

(72) Inventors: Sachiko KOBAYASHI, Ota Tokyo (JP); Kazuhiro TAKAHATA, Yokohama Kanagawa (JP); Satoshi MITSUGI, Kawasaki Kanagawa (JP)

(73) Assignee: Kioxia Corporation, Tokyo (JP)

(21) Appl. No.: 18/598,201

(22) Filed: Mar. 7, 2024

(30) Foreign Application Priority Data
Mar. 20, 2023 (JP) 2023-043866

(51) Int. Cl. B41C 1/10; G03F 7/00; G06F 30/392

(52) U.S. Cl. CPC B41C 1/10; G03F 7/0002; G06F 30/392

(57) ABSTRACT

A pattern design method according to an embodiment is a method to design a pattern of a template used for an imprint process. The imprint process serves to form a predetermined pattern by pressing a shot surface of the template against a surface of a processed layer. The method includes setting an outer edge coverage range corresponding to an outer edge region located a predetermined distance inside an edge of the shot surface of the template. The outer edge coverage range is set to be different from an inner coverage range corresponding to an inner region inside the outer edge region. The method includes designing a pattern in the outer edge region to have a coverage falling within the outer edge coverage range. The method includes designing a pattern in the inner region to have a coverage falling within the inner coverage range.

### CROSS-REFERENCE TO RELATED APPLICATIONS

This application is based upon and claims the benefit of priority from Japanese Patent Application No. 2023-043866, filed on Mar. 20, 2023, the entire contents of which are incorporated herein by reference.

### FIELD

Embodiments described herein relate generally to a pattern design method, a template manufacturing method, and a pattern design apparatus.

### BACKGROUND

In a manufacturing process for a semiconductor device, a step and repeat imprint process is used for forming a pattern on a processed layer (a layer to be processed), such as a resist, by sequentially pressing a template having a predetermined pattern against plural shot regions provided on a surface of the processed layer.

In such an imprint process, a processed layer with fluidity (for example, uncured resist; resist before curing) may flow beyond a boundary between shot regions, causing a malfunction.

### BRIEF DESCRIPTION OF THE DRAWINGS

FIG. 1 is a diagram illustrating an exemplary configuration of an imprint apparatus according to a first embodiment;

FIG. 2 is a diagram illustrating an exemplary configuration of a shot surface of a template according to the first embodiment;

FIG. 3 is a diagram illustrating an example of shot regions provided on a substrate according to the first embodiment;

FIG. 4 is a diagram illustrating an example of a stamping operation according to the first embodiment;

FIG. 5A is an exemplary diagram illustrating a state that pressing of the template against an uncured resist is started in a preceding shot region, according to the first embodiment;

FIG. 5B is an exemplary diagram illustrating a state that exposure is performed with the template lowered to a predetermined position in the preceding shot region, according to the first embodiment;

FIG. 5C is an exemplary diagram illustrating a state that lifting of the template is started after the exposure is finished in the preceding shot region, according to the first embodiment;

FIG. 5D is an exemplary diagram illustrating a state that the lifting of the template is finished in the preceding shot region, according to the first embodiment;

FIG. 6A is an exemplary diagram illustrating a state that pressing of the template against an uncured resist is started in a subsequent shot region, according to the first embodiment;

FIG. 6B is an exemplary diagram illustrating a state that exposure is performed with the template lowered to a predetermined position in the subsequent shot region, according to the first embodiment;

FIG. 6C is an exemplary diagram illustrating a state that lifting of the template is started after the exposure is finished in the subsequent shot region, according to the first embodiment;

FIG. 6D is an exemplary diagram illustrating a state that the lifting of the template is finished in the subsequent shot region, according to the first embodiment;

FIG. 7 is a diagram illustrating an exemplary configuration of a pattern design apparatus according to the first embodiment;

FIG. 8 is a diagram illustrating an example of a coverage according to the first embodiment;

FIG. 9A is a diagram illustrating an example of a flow amount of the uncured resist occurring when coverage is 100%, according to the first embodiment;

FIG. 9B is a diagram illustrating an example of a flow amount of the uncured resist occurring when coverage is 70%, according to the first embodiment;

FIG. 9C is a diagram illustrating an example of a flow amount of the uncured resist occurring when coverage is 50%in the first embodiment;

FIG. 10 is a diagram illustrating an example of outer edge regions, an inner region, preceding regions, and subsequent regions on the shot surface according to the first embodiment;

FIG. 11 is a diagram illustrating an example of a main region and a kerf region on the shot surface according to the first embodiment;

FIG. 12 is a table illustrating an example of coverage definition information according to the first embodiment;

FIG. 13 is a flowchart illustrating an exemplary processing by the pattern design apparatus according to the first embodiment;

FIG. 14 is a diagram illustrating an exemplary configuration of a pattern design apparatus according to a second embodiment;

FIG. 15A is a diagram illustrating an exemplary prediction method to predict influence of a flow of an uncured resist according to the second embodiment; and

FIG. 15B is a diagram illustrating an example of a boundary region after adjustment according to the second embodiment.

### DETAILED DESCRIPTION

According to one embodiment of the present disclosure, a pattern design method to design a pattern of a template used for an imprint process is provided. The imprint process serves to form a predetermined pattern by pressing a shot surface of the template against a surface of a processed layer. The pattern design method includes setting an outer edge coverage range corresponding to an outer edge region located a predetermined distance inside an edge of the shot surface of the template. The outer edge coverage range is set to be different from an inner coverage range corresponding to an inner region inside the outer edge region. The pattern design method includes designing a pattern in the outer edge region to have a coverage falling within the outer edge coverage range. The pattern design method includes designing a pattern in the inner region to have a coverage falling within the inner coverage range.

Hereinafter, the present invention will be described in detail with reference to the drawings. Note that the present invention is not limited to the following embodiments. Component elements in the following embodiments include component elements which are readily conceivable by a person skilled in the art or which are substantially identical.

### First Embodiment

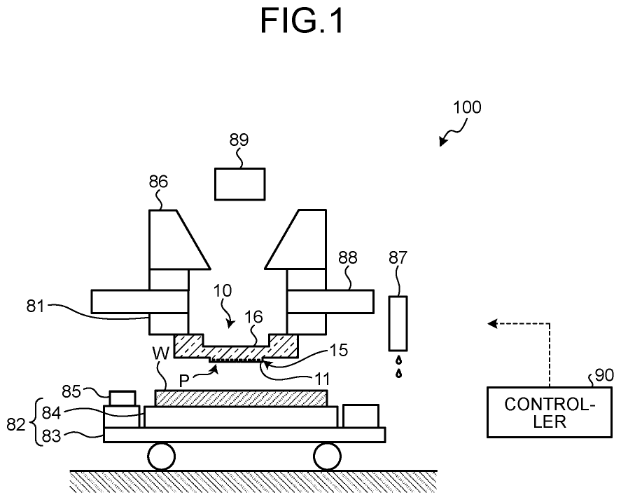

FIG. 1 is a diagram illustrating an exemplary configuration of an imprint apparatus 100 according to a first embodiment. The imprint apparatus 100 is an apparatus capable of performing a step and repeat imprint process to form a predetermined pattern on a processed layer (that is a layer to be processed), such as a resist applied onto a substrate W, by pressing a template 10 against the processed layer. The step and repeat method is a method of sequentially pressing the template 10 against shot regions defined on the processed layer in a predetermined order.

The imprint apparatus 100 according to the present embodiment includes a template stage 81, a mount 82, a reference mark 85, an alignment sensor 86, a liquid dropping device 87, a stage base 88, a light source 89, and a controller (control circuit) 90.

The mount 82 includes a wafer chuck 84 and a main body 83. The wafer chuck 84 fixes the substrate W to be processed at a predetermined position on the main body 83. The mount 82 is provided with the reference mark 85. The reference mark 85 is used for positioning to fix the substrate W on the mount 82. The mount 82 is configured to mount the substrate W, and moves in a plane (in a horizontal plane) parallel with the mounted substrate W. The mount 82 moves the substrate W under the liquid dropping device 87 upon dropping the resist (example of the processed layer) onto the substrate W, and moves the substrate W under the template 10 upon performing transfer processing to the substrate W. Note that the method of applying the resist onto the substrate W is not limited to the above description. For example, another device may apply the resist to the substrate W by using a spin coating method or the like. In this configuration, the substrate W to which the resist has been coated is placed on the mount 82. The substrate W may be, for example, a semiconductor substrate such as a silicon wafer.

The stage base 88 is configured to support the template 10 by the template stage 81 and to be movable in a vertical direction and a horizontal direction. This configuration makes it possible to implement the step and repeat imprint process in which a shot surface 11 of the template 10 is sequentially pressed against the shot regions defined on the substrate W (resist). On the stage base 88, an alignment sensor 86 is provided. The alignment sensor 86 performs detection of the position of the substrate W, detection of the position of the template 10, and so forth.

The template 10 is made of a transparent material that transmits ultraviolet rays. The template 10 includes a mesa portion 15 that has a shape protruding downward. The mesa portion 15 has an upper surface portion in which a counterbore 16 is formed. Additionally, the mesa portion 15 has a lower surface portion on which the shot surface 11 is formed, which is pressed against the processed layer (resist in the present embodiment) on the substrate W. A predetermined pattern P is formed on the shot surface 11. As described later, the pattern P includes an actual pattern that contributes to a circuit configuration of a semiconductor device, a dummy pattern that does not contribute to the circuit configuration, and/or a mark pattern such as an alignment mark.

The liquid dropping device 87 is a device that uses an ink-jet method to drop the resist onto the substrate W. The liquid dropping device 87 includes an ink-jet head that has a plurality of micropores to eject droplets of the resist to drop the droplets of the resist onto the substrate W.

The resist is a resin-based mask material. The resist may be a photocurable resin cured by irradiation with light, a thermosetting resin cured by application of heat, or the like. In the present embodiment, it is assumed that a resist of the photocurable resin is used.

The light source 89 is, for example, a device that emits ultraviolet light. The light source 89 is provided above the stage base 88. The light source 89 emits light from above the template 10, while the template 10 is pressed against the resist. Therefore, the resist to which the pattern P of the template 10 has been transferred can be cured.

The controller 90 controls the template stage 81, the mount 82, the reference mark 85, the alignment sensor 86, the liquid dropping device 87, the stage base 88, and the light source 89.

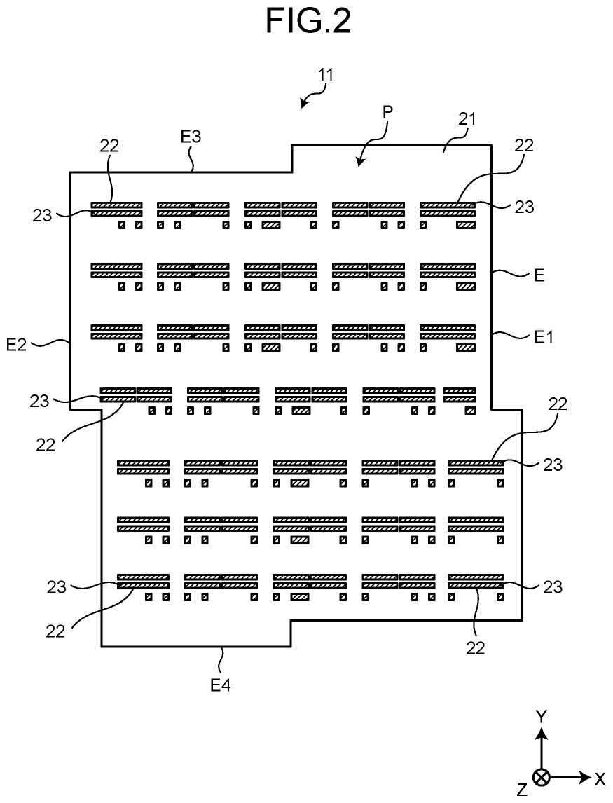

FIG. 2 is a bottom view of an exemplary configuration of the shot surface 11 of the template 10 according to the first embodiment. FIG. 2 is a view of the shot surface 11 of the template 10 as viewed from below. In FIG. 2, a direction X indicates a direction from the left side to the right side of the drawing, a direction Y indicates a direction from the lower side to the upper side of the drawing, and a direction Z indicates a direction from the front side to the back side of the drawing. These directions X, Y, and Z correspond to the directions X, Y, and Z in the other drawings.

As illustrated in FIG. 2, the pattern P is formed in a region that is inside an edge E of the shot surface 11. The edge E of the shot surface 11 of the present embodiment has a jigsaw shape. The jigsaw shape refers to a shape that each side constituting the edge E is refracted, and when the shot surfaces 11 are arranged to be adjacent to each other, adjacent sides mesh with each other. The edge E of the present embodiment is formed such that, when two shot surfaces 11 are arranged so as to be adjacent to each other in a horizontal direction (in the X direction), a right side portion E1 and a left side portion E2 mesh with each other and when two shot surfaces 11 are arranged so as to be arranged in a vertical direction (in the Y direction), an upper side portion E3 and a lower side portion E4 mesh with each other. Note that the mode of the jigsaw shape is not limited this description.

In the region inside the edge E described above, a plurality of protrusions 22 that is formed to protrude in a vertical direction (opposite direction to the Z direction) from a bottom surface (XY plane) 21 of the shot surface 11 is formed. In FIG. 2, hatched portions each represent an end surface 23 of each of the protrusions 22. The end surface 23 is a portion that makes contact with the processed layer first when the template 10 is pressed against the processed layer. The pattern P is formed by a combination of the shapes and arrangement of such protrusions 22.

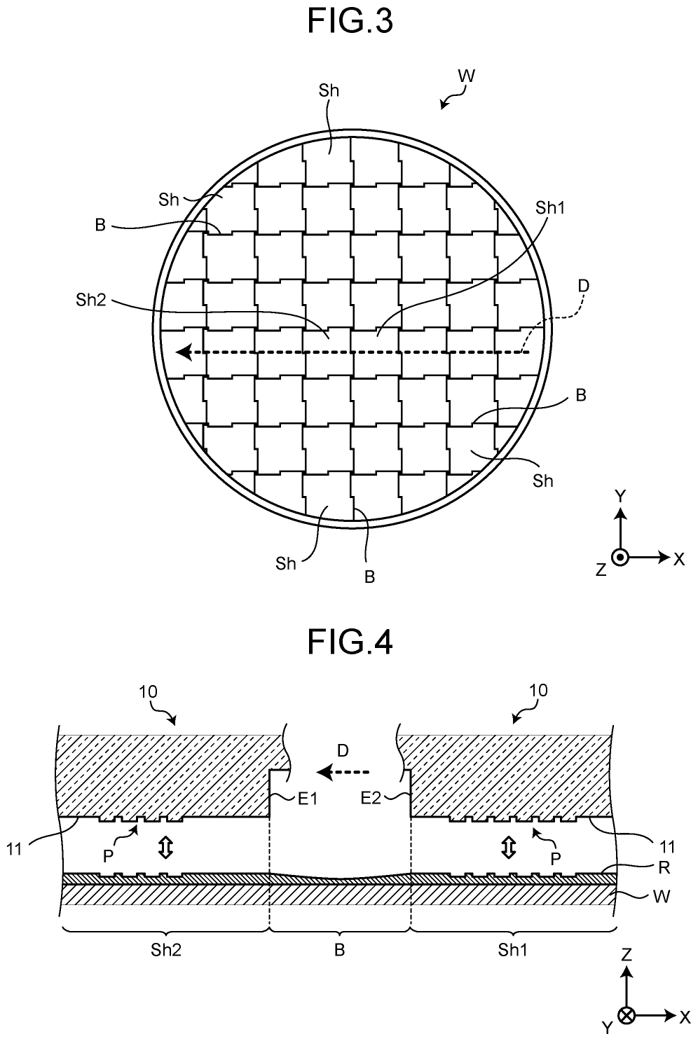

FIG. 3 is a top view of an example of a plurality of shot regions Sh provided on the substrate W according to the first embodiment. As illustrated in FIG. 3, the shot regions Sh are set on the surface of the substrate W (including the processed layer such as the resist). Each of the shot regions Sh is a region against which the shot surface 11 of the template 10 described above is sequentially pressed. In the present embodiment, the shot region Sh has a jigsaw shape as in the edge E of the shot surface 11. In FIG. 3, a boundary region B is a region of a gap between the adjacent shot regions Sh.

For the shot regions Sh, a step and repeat stamping operation (operation of pressing the shot surface 11 against the processed layer) using the template 10 described above is sequentially performed in a predetermined order. In FIG. 3, a stamping direction D represents an example of a direction in which the stamping operation is sequentially performed. This direction extends from the right to the left in the present example. Note that the stamping direction D may change with a region on the substrate W. In one example, the stamping direction D may be horizontally reversed for each row of a plurality of shot regions Sh arranged in a horizontal direction (direction parallel to the X direction), or may be a vertical direction (direction parallel to the Y direction). In FIG. 3, a preceding shot region Sh1 and a subsequent shot region Sh2 adjacent in the stamping direction D are illustrated. The preceding shot region Sh1 is a shot region where the stamping operation is performed first, and the subsequent shot region Sh2 is a shot region where the stamping operation is performed next to the preceding shot region Sh1.

FIG. 4 is a diagram illustrating an example of the stamping operation according to the first embodiment. FIG. 4 illustrates a situation when a resist R as the processed layer is applied to the surface of the substrate W and a pattern is formed in the preceding shot region Sh1 and subsequent shot region Sh2 adjacent to each other in the stamping direction D.

First, the template 10 positioned above the preceding shot region Sh1 is lowered, and the shot surface 11 is pressed against the resist R. Thereafter, exposure is performed while the shot surface 11 is pressed against the resist R to cure the resist R in the preceding shot region Sh1. Then, the template 10 is lifted and released from the resist R.

Next, the template 10 is moved in the stamping direction D and placed above the subsequent shot region Sh2. At this time, the boundary region B having a predetermined width is formed between the preceding shot region Sh1 and the subsequent shot region Sh2. Then, the template 10 positioned above the subsequent shot region Sh2 is lowered, and the shot surface 11 is pressed against the resist R. Thereafter, exposure is performed while the shot surface 11 is pressed against the resist R to cure the resist R in the subsequent shot region Sh2. Then, the template 10 is lifted and released from the resist R.

Sequentially performing the processing as described above, the same pattern as the pattern P of the template 10 can be formed in each of the shot regions Sh.

In the step and repeat imprint process described above, a malfunction may be caused due to flow of the resist R uncured. Hereinafter, the uncured resist R with fluidity is referred to as an uncured resist Rf, and the resist R having cured by exposure is referred to as a cured resist Rs.

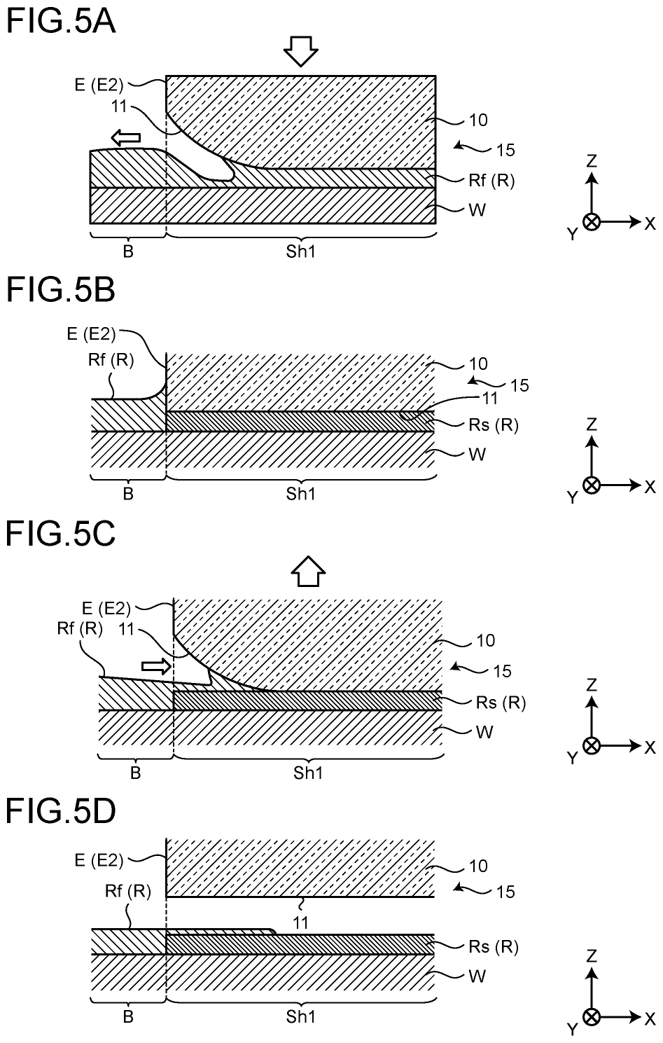

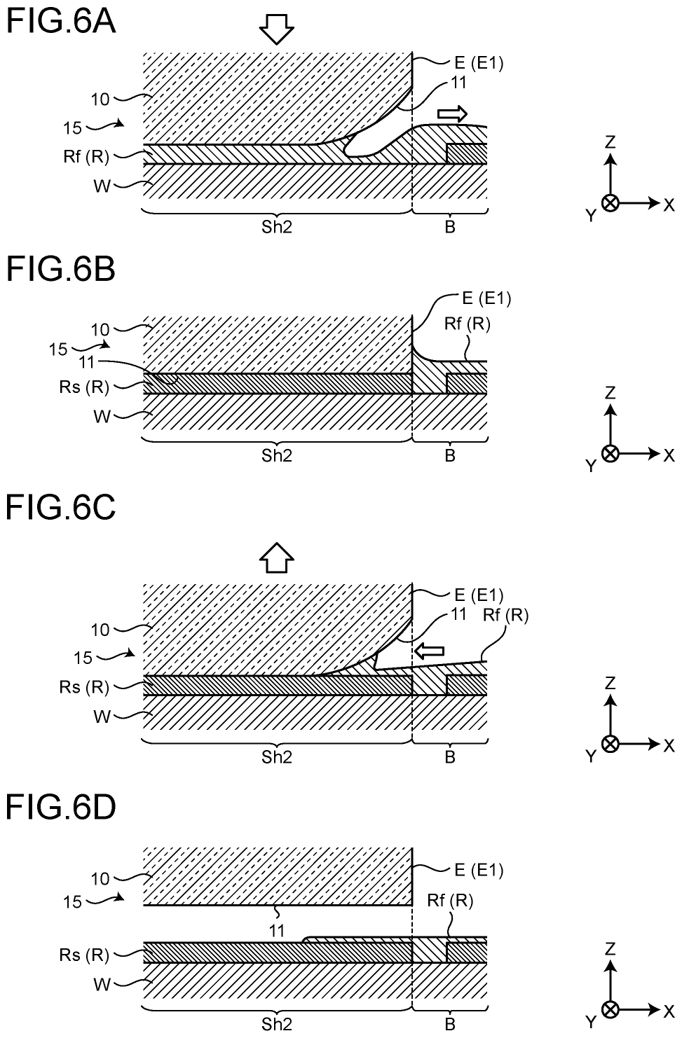

FIGS. 5A to 5D are exemplary diagrams illustrating influence of the uncured resist Rf on the preceding shot region Sh1. FIGS. 6A to 6D are diagrams illustrating an example of the influence of the uncured resist Rf on the subsequent shot region Sh2. In FIGS. 5A to 5D and FIGS. 6A to 6D, illustration of the pattern P formed on the shot surface 11 is omitted.

FIG. 5A illustrates a state that pressing of the template 10 against the uncured resist Rf is started (upon starting stamping) in the preceding shot region Sh1. At this time, the mesa portion 15 of the template 10 is slightly bent downward due to a back pressure on the template 10 and surface tension of a liquid surface of the uncured resist Rf, and a portion near the edge E (the left side portion E2 in FIGS. 5A to 5D) of the shot surface 11 is slightly curved. Then, the uncured resist Rf in the preceding shot region Sh1 flows out to the boundary region B due to pressure caused by the lowering of the template 10.

FIG. 5B illustrates a state that exposure is performed (upon exposure) with the template 10 lowered to the predetermined position in the preceding shot region Sh1. By the exposure, the uncured resist Rf is changed to the cured resist Rs. At this time, the uncured resist Rf flowing out to the boundary region B due to the lowering of the template 10 described above is blocked by the edge E of the template 10, and a side surface of the mesa portion 15 becomes wet with the uncured resist Rf due to the effect of the surface tension of the uncured resist Rf.

FIG. 5C illustrates a state that lifting of the template 10 is started (upon starting demolding) after the exposure is finished in the preceding shot region Sh1. At this time, the uncured resist Rf blocked by the edge E of the template 10 in the boundary region B flows into the preceding shot region Sh1 due to the effect of the surface tension or the like.

FIG. 5D illustrates a state that the lifting of the template 10 is finished (upon finishing demolding) in the preceding shot region Sh1. At this time, the uncured resist Rf flowing in from the boundary region B described above stays on the cured resist Rs.

FIG. 6A illustrates a state that pressing of the template 10 against the uncured resist Rf is started (upon starting stamping) in the subsequent shot region Sh2. As in FIG. 5A, at this time, the mesa portion 15 of the template 10 is slightly bent downward due to the back pressure on the template 10 and the surface tension of the liquid surface of the uncured resist Rf, and a portion near the edge E (the right side portion E1 in FIGS. 6A to 6D) of the shot surface 11 is slightly curved. Then, the uncured resist Rf in the subsequent shot region Sh2 flows out to the boundary region B due to the pressure caused by the lowering of the template 10.

FIG. 6B illustrates a state that exposure is performed (upon exposure) with the template 10 lowered to the predetermined position in the subsequent shot region Sh2. By the exposure, the uncured resist Rf is changed to the cured resist Rs. At this time, the uncured resist Rf flowing out to the boundary region B due to the lowering of the template 10 described above is blocked by the edge E of the template 10, and a side surface of the mesa portion 15 becomes wet with the uncured resist Rf due to the effect of the surface tension of the uncured resist Rf.

FIG. 6C illustrates a state that lifting of the template 10 is started (upon starting demolding) after the exposure is finished in the subsequent shot region Sh2. At this time, the uncured resist Rf blocked by the edge E of the template 10 in the boundary region B flows into the subsequent shot region Sh2 due to the effect of the surface tension or the like.

FIG. 6D illustrates a state that the lifting of the template 10 is finished (upon finishing demolding) in the subsequent shot region Sh2. At this time, the uncured resist Rf flowing in from the boundary region B described above stays on the cured resist Rs.

As described above, when the imprint process is performed by using the step and repeat method, the flow of the uncured resist Rf between the preceding shot region Sh1 and the boundary region B and between the subsequent shot region Sh2 and the boundary region B may cause a stain on a surface of the cured resist Rs on which the pattern has already been formed. Note that the mode of the influence of the uncured resist Rf is not limited to the above description.

The influence of the flow of the uncured resist Rf described above may change with the coverage of the pattern P formed on the template 10. In particular, the pressure to cause the uncured resist Rf to flow out to the boundary region B from each shot region Sh is greatly affected by the coverage of the pattern P formed in a region in the vicinity of the edge E of the shot surface 11. Therefore, the present embodiment provides a method for forming the pattern P of the template 10 that makes it possible to suppress the influence of the flow of the uncured resist Rf.

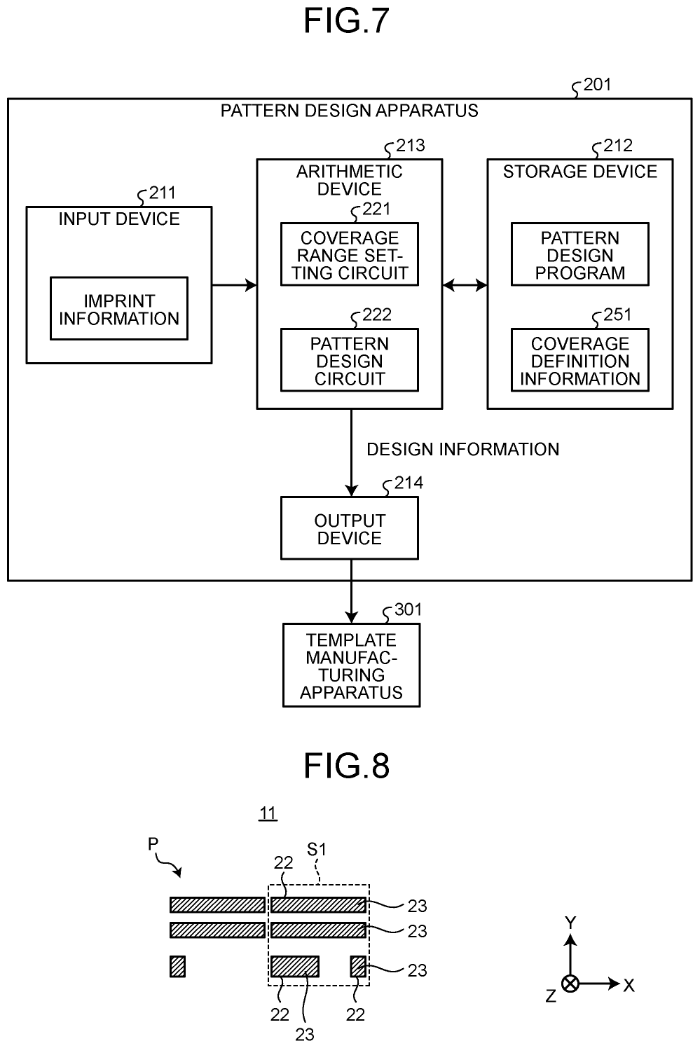

FIG. 7 is a block diagram illustrating an exemplary configuration of a pattern design apparatus 201 according to the first embodiment. The pattern design apparatus 201 is an information processing apparatus that performs processing for designing the pattern P of the template 10.

A hardware configuration of the pattern design apparatus 201 is not particularly limited, and may be, for example, a configuration similar to that of a general-purpose computer. In this case, the pattern design apparatus 201 includes, for example, a central processing unit (CPU), a random access memory (RAM), a read only memory (ROM), a storage, a user interface, a communication interface, and the like, and the CPU is allowed to execute predetermined arithmetic processing and the like by using the RAM as a work area according to a program stored in the ROM, the storage, or the like. The pattern design apparatus 201 may be configured by a single computer, or may be a system configured by cooperation of a plurality of computers, electronic devices, and the like.

The pattern design apparatus 201 includes an input device 211, a storage device 212, an arithmetic device 213, and an output device 214.

The input device 211 is a device by which various information necessary for designing the pattern P is input. The input device 211 may be, for example, a device configured to read and write data from and to a predetermined storage medium, a device configured to communicate with another electronic device, a keyboard, a touch panel, or the like that receives a user's input operation. The input device 211 of the present embodiment is configured to receive an input of imprint information. The imprint information is necessary for performing the step and repeat imprint process described above. The imprint information can include, for example, information about the substrate W to be used, information about the shot region Sh, the stamping direction D, information about a pattern to be formed on the resist R, and the like.

The storage device 212 is a device that stores various information necessary for designing the pattern P, and can be configured using, for example, an appropriate non-volatile memory, volatile memory, or the like. Data stored in the storage device 212 of the present embodiment includes a pattern design program and coverage definition information 251. The pattern design program is a program that causes the arithmetic device 213 to execute arithmetic processing and the like for designing the pattern P.

The coverage definition information 251 is information for determining a coverage range used for designing the pattern P. The coverage range is a range of coverage to be complied with when the pattern P is formed on the shot surface 11 of the template 10. In the present embodiment, the shot surface 11 is segmented into plural regions, and the coverage range is set for each of the regions (described in detail later). The coverage definition information 251 of the present embodiment includes information representing a relationship between each region on the shot surface 11 and the coverage range.

The arithmetic device 213 is a device that executes various arithmetic processing and the like for designing the pattern P, and can be configured using, for example, a CPU, an application specific integrated circuit (ASIC), a field programmable gate array (FPGA), or the like.

The arithmetic device 213 includes, a coverage range setting circuit 221 and a pattern design circuit 222.

The coverage range setting circuit 221 sets the coverage range for each of the regions set on the shot surface 11 of the template 10, on the basis of the imprint information, the coverage definition information 251, and the like.

The pattern design circuit 222 designs the pattern P such that each region on the shot surface 11 has a coverage falling within a corresponding coverage range, on the basis of the imprint information, a result of the setting by the coverage range setting circuit 221, and the like.

The output device 214 is a device that outputs various information generated by the arithmetic device 213. The output device 214 may be, for example, a device establishing communication with an external device, a display, a speaker, or the like. The output device 214 of the present embodiment outputs design information representing the pattern P designed by the arithmetic device 213 to a template manufacturing apparatus 301.

The template manufacturing apparatus 301 is a device or system that is configured to form the pattern P on the shot surface 11 of the template 10 on the basis of the design information. The template manufacturing apparatus 301 manufactures the template 10 on which the pattern P designed by the arithmetic device 213 is formed.

FIG. 8 is a diagram illustrating an example of the coverage according to the first embodiment. FIG. 8 illustrates part of the pattern P formed on the shot surface 11 of the template 10. The coverage of the present embodiment is a ratio of the total area of the end surfaces 23 of the protrusions 22 constituting the pattern P in a predetermined region S1 to the area of the predetermined region S1 on the shot surface 11. For example, when the predetermined region S1 is a square of 50 μm×50 μm (area: 2500 μm²) and the end surfaces 23 has a total area of 1250 μm², the coverage is 50%.

As described above, the flow of the uncured resist Rf between the shot region Sh and the boundary region B due to the stamping operation causes the stain on the pattern formed on the cured resist Rs. A flow amount of such an uncured resist Rf during the stamping operation changes with the coverage of the pattern P formed on the template 10.

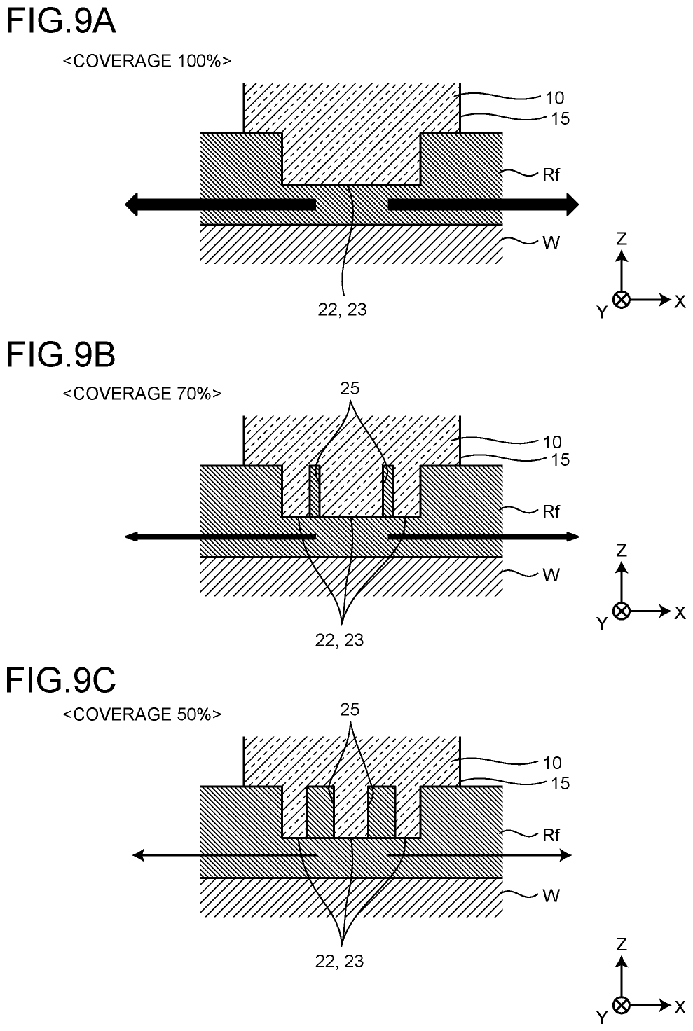

FIGS. 9A to 9C are diagrams each illustrating an example of a relationship between the coverage of the pattern P and the flow amount of the uncured resist Rf according to the first embodiment. FIGS. 9A to 9C conceptually illustrate the flow amounts of the uncured resist Rf when the coverage is 100%, 70%, and 50%, respectively. In FIGS. 9A to 9C, arrows each have a thickness corresponding to the flow amount of the uncured resist Rf. The thicker the arrow, the larger the flow amount.

As illustrated in FIGS. 9A to 9C, the smaller the coverage, the more uncured resist Rf is held in recesses 25 (spaces between the protrusions 22) formed in the mesa portion 15 of the template 10, and the flow amount of the uncured resist Rf decreases. Such a phenomenon becomes more remarkable in a region closer to the edge E of the shot surface 11. When the coverage of the pattern P formed in the region closer to the edge E is high, the flow amount of the uncured resist Rf between the shot region Sh and the boundary region B increases. Therefore, the arithmetic device 213 (coverage range setting circuit 221) of the present embodiment sets an optimized coverage range for each region on the shot surface 11 so as to reduce the influence of the flow of the uncured resist Rf, in consideration of a relationship between the coverage and the flow amount of the uncured resist Rf.

Hereinafter, an example of the relationship between each region set on the shot surface 11 and the coverage range will be described.

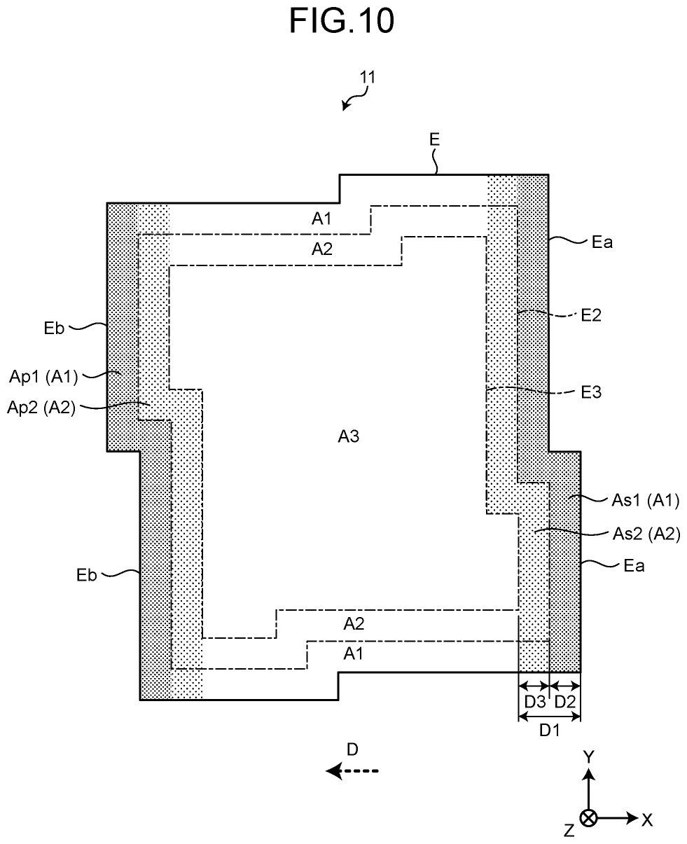

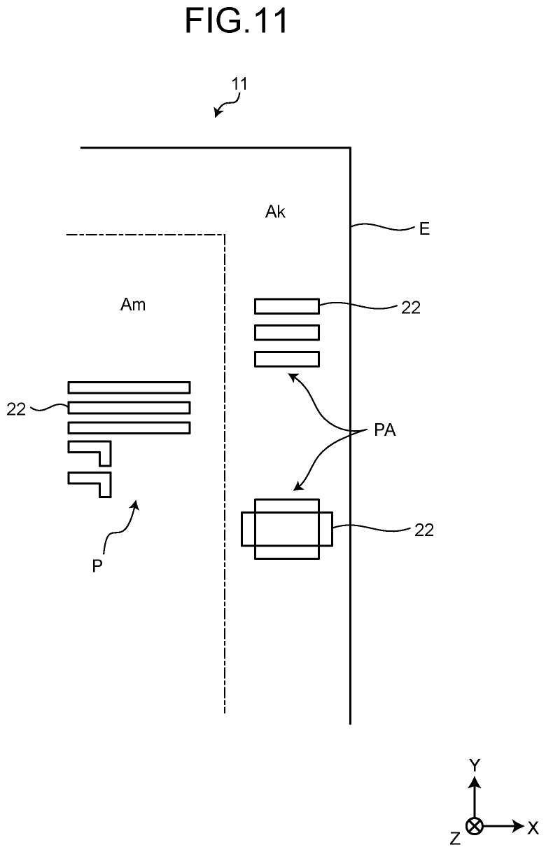

FIG. 10 is a bottom view of an example of outer edge regions A1 and A2, an inner region A3, preceding regions Ap1 and Ap2, and subsequent regions As1 and As2 on the shot surface 11 according to the first embodiment. The outer edge regions A1 and A2 are regions that are located a predetermined distance D1 inside the edge E of the shot surface 11. The outer edge regions A1 and A2 of the present embodiment include two regions that are a first outer edge region A1 and a second outer edge region A2. The first outer edge region A1 is a region located a predetermined distance D2 (example of a first predetermined distance) inside the edge E of the shot surface 11. The second outer edge region A2 is a region located a predetermined distance D3 (an example of a second predetermined distance) inside an inner edge E2 of the first outer edge region A1. The inner region A3 is a region located inside an inner edge E3 of the outer edge region (the second outer edge region A2 in the present embodiment).

The outer edge coverage range that is a coverage range corresponding to the outer edge regions A1 and A2 is set to be different from the inner coverage range that is a coverage range corresponding to the inner region A3. The outer edge regions A1 and A2 are regions having a greater influence on the flow of the uncured resist Rf than that of the inner region A3. Therefore, the outer edge coverage range should be set under a stricter condition than that of the inner coverage range. Specifically, for example, it is considered to set the outer edge coverage range to be smaller than the inner coverage range, or to set an upper limit value of the outer edge coverage range to be smaller than an upper limit value of the inner coverage range. In one example, the outer edge coverage range is set to 30% to 60%, and the inner coverage range is set to 20%to 70%. Note that these numerical values are merely an example, and specific numerical values should be appropriately set according to a usage condition.

Moreover, a first outer edge coverage range that is a coverage range corresponding to the first outer edge region A1 is set to be different from a second outer edge coverage range that is a coverage range corresponding to the second outer edge region A2. The first outer edge region A1 is a region having a greater influence on the flow of the uncured resist Rf than that of the second outer edge region A2, and therefore, the first outer edge coverage range is set under a stricter condition than that of the second outer edge coverage range. Specifically, for example, it is considered to set the first outer edge coverage range to be smaller than the second outer edge coverage range, or to set an upper limit value of the first outer edge coverage range to be smaller than an upper limit value of the second outer edge coverage range. In one example, the first outer edge coverage range is set to 45%to 55%, and the second outer edge coverage range is set to 30%to 60%. Note that these numerical values are merely an example, and specific numerical values should be appropriately set according to the usage condition.

The shot surface 11 includes the preceding regions Ap1 and Ap2 and the subsequent regions As1 and As2. The preceding regions Ap1 and Ap2 are regions that are located the predetermined distance D1 inside an edge Eb of the shot surface 11 on the downstream side in the stamping direction D. The preceding regions Ap1 and Ap2 are regions adjacent to a shot region Sh for which the stamping operation has not yet been performed in the imprint process using the step and repeat method. The preceding regions Ap1 and Ap2 of the present embodiment include two regions that are a first preceding region Ap1 and a second preceding region Ap2. The first preceding region Ap1 is a region that is located the predetermined distance D2 inside the downstream edge Eb on the downstream side. The second preceding region Ap2 is a region that is located the predetermined distance D3 inside the inner edge E2 of the first preceding region Ap1.

The subsequent regions As1 and As2 are regions located the predetermined distance D1 inside an edge Ea on the upstream side in the stamping direction D of the shot surface 11. The subsequent regions As1 and As2 are regions adjacent to a shot region Sh for which the stamping operation has already been performed in the imprint process using the step and repeat method. The subsequent regions As1 and As2 of the present embodiment include two regions that are a first subsequent region As1 and a second subsequent region As2. The first subsequent region As1 is a region located the predetermined distance D2 inside the upstream edge Ea on the upstream side. The second subsequent region As2 is a region located the predetermined distance D3 inside the inner edge E2 of the first subsequent region As1.

A preceding coverage range that is a coverage range corresponding to the preceding regions Ap1 and Ap2 is set to be different from a subsequent coverage range that is a coverage range corresponding to the subsequent regions As1 and As2. The preceding regions Ap1 and Ap2 are regions having a greater influence on the flow (outflow and re-entrance) of the uncured resist Rf than that of the subsequent regions As1 and As2. Therefore, the preceding coverage range should be set under a stricter condition than that of the subsequent coverage range. Specifically, for example, it is considered to set the preceding coverage range to be smaller than the subsequent coverage range, or to set an upper limit value of the preceding coverage range to be smaller than an upper limit value of the subsequent coverage range.

Moreover, a first preceding coverage range that is a coverage range corresponding to the first preceding region Ap1 is set to be different from a second preceding coverage range that is a coverage range corresponding to the second preceding region Ap2. A first subsequent coverage range that is a coverage range corresponding to the first subsequent region As1 is set to be different from a second subsequent coverage range that is a coverage range corresponding to the second subsequent region As2. The first preceding region Ap1 is a region having a greater influence on the flow of the uncured resist Rf than that of the second preceding region Ap2. Therefore, the first preceding coverage range should be set under a stricter condition than that of the second preceding coverage range. In addition, the first subsequent region As1 is a region having a greater influence on the flow of the uncured resist Rf than that of the second subsequent region As2. Therefore, the first subsequent coverage range should be set under a stricter condition than that of the second subsequent coverage range. Specifically, for example, it is considered to set the first preceding coverage range to be smaller than the second preceding coverage range, or to set an upper limit value of the first preceding coverage range to be smaller than an upper limit value of the second preceding coverage range. In addition, it is considered to set the first subsequent coverage range to be smaller than the second subsequent coverage range, or to set an upper limit value of the first subsequent coverage range to be smaller than an upper limit value of the second subsequent coverage range. Note that specific numerical values of the preceding coverage range and the subsequent coverage range should be appropriately set according to the usage condition.

FIG. 11 is a diagram illustrating an example of a main region Am and a kerf region Ak on the shot surface 11 according to the first embodiment. The main region Am is a region in which the pattern P corresponding to a circuit pattern of the semiconductor device to be manufactured is formed. The kerf region Ak is a region that is formed around the main region Am and in which no pattern P corresponding to the circuit pattern is formed. The kerf region Ak corresponds to a dicing line between the semiconductor devices (chips). In the kerf region Ak of the present embodiment, the pattern P including an alignment pattern PA for forming the alignment mark for alignment on the processed layer (resist) on the substrate W is formed. In FIG. 11, an alternate long and short dash line indicates a boundary line between the main region Am and the kerf region Ak. The pattern P and the alignment pattern PA are formed so as not to cross the boundary line. In the main region Am and the kerf region Ak, the dummy pattern may be formed, which is not connected to the actual pattern and which has an electrically floating state.

A main coverage range, which is a coverage range corresponding to the main region Am, is set to be different from a kerf coverage range that is a coverage range corresponding to the kerf region Ak. The main region Am is a region from which the influence of the flow of the uncured resist Rf needs to be more strictly eliminated than the kerf region Ak. Therefore, the main coverage range should be set under a stricter condition than that of the kerf coverage range. Specifically, for example, it is considered to set the main coverage range smaller than the kerf coverage range, or to set an upper limit value of the main coverage range to be smaller than an upper limit value of the kerf coverage range. Note that specific numerical values of the main coverage range and the kerf coverage range should be appropriately set according to the usage condition.

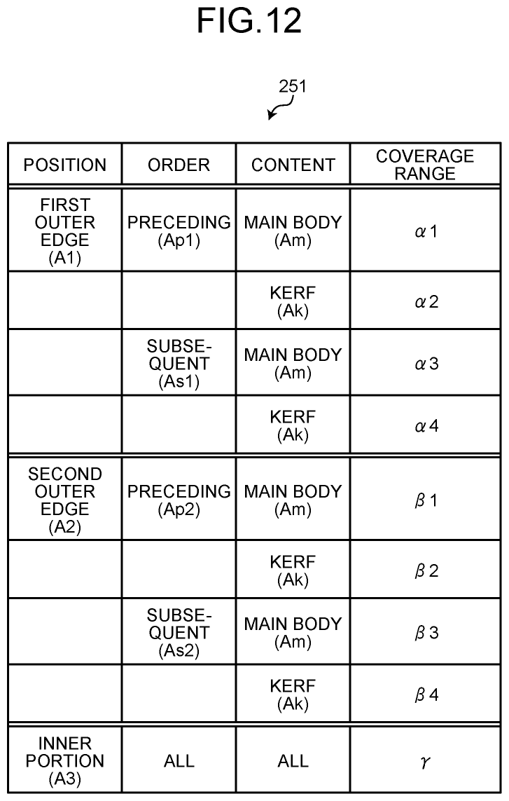

FIG. 12 is a table illustrating an example of the coverage definition information 251 according to the first embodiment. The coverage definition information 251 is information that defines relationships between various regions and the coverage ranges described above. In FIG. 12, an item “position” represents whether a target region as a target for setting a coverage range corresponds to which one of the outer edge regions A1 and A2 and the inner region A3. An item “order” represents whether the target region corresponds to which one of the preceding regions Ap1 and Ap2 and the subsequent regions As1 and As2. An item “content” represents whether the target region corresponds to the main region Am or the kerf region Ak.

In the example illustrated in FIG. 12, the coverage range is set to α1 when the target region is the first outer edge region A1, the preceding region (first preceding region) Ap1, and the main region Am. When the target region is the first outer edge region A1, the preceding region Ap1, and the kerf region Ak, the coverage range is set to α2. At this time, strictness is required for the main region Am than for the kerf region Ak, and therefore, α1 has a value (for example, a numerical range having a smaller range and/or smaller upper limit value) stricter than that of α2.

When the target region is the first outer edge region A1, the subsequent region (first subsequent region) As1, and the main region Am, the coverage range is set to α3. When the target region is the first outer edge region A1, the subsequent region As1, and the kerf region Ak, the coverage range is set to α4. At this time, strictness is required for the main region Am than for the kerf region Ak, and therefore, α3 has a value stricter than that of α4. In addition, strictness is required for the preceding region Ap1 than for the subsequent region As1, and therefore, α1 has a value stricter than that of α3, and α2 has a value stricter than that of α4.

When the target region is the second outer edge region A2, the preceding region (second preceding region) Ap2, and the main region Am, the coverage range is set to β1. When the target region is the second outer edge region A2, the preceding region Ap2, and the kerf region Ak, the coverage range is set to β2. At this time, strictness is required for the main region Am than for the kerf region Ak, and therefore, β1 has a value stricter than that of β2. In addition, strictness is required for the first outer edge region A1 than for the second outer edge region A2, and therefore, α1 has a value stricter than β1, and α2 has a value stricter than that of β2.

When the target region is the second outer edge region A2, the subsequent region (second subsequent region) As2, and the main region Am, the coverage range is set to β3. When the target region is the second outer edge region A2, the subsequent region As2, and the kerf region Ak, the coverage range is set to β4. At this time, strictness is required for the main region Am than for the kerf region Ak, and therefore, β3 has a value stricter than that of β4. In addition, strictness is required for the preceding region Ap2 than for the subsequent region As2, and therefore, β1 is a value stricter than β3, and β2 has a value stricter than that of β4. In addition, strictness is required for the first outer edge region A1 than for the second outer edge region A2, and therefore, α3 is a value stricter than that of β3, and α4 has a value stricter than that of β4.

When the target region is the inner region A3, the coverage range is set to γ regardless of the “order” and the “content”. It is preferable to set γ appropriately on the basis of a conventional method or the like, but y may have, for example, a value (for example, a numerical range having a larger range and/or larger upper limit value) less strict than that of any of α1 to α4 and β1 to β4.

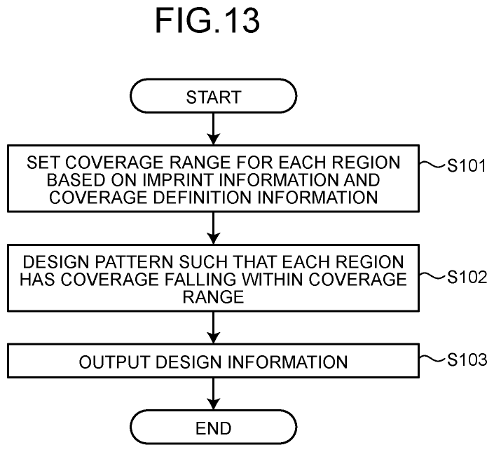

FIG. 13 is a flowchart illustrating an exemplary processing by the pattern design apparatus 201 according to the first embodiment. The arithmetic device 213 (coverage range setting circuit 221) sets the coverage range for each of the regions defined on the shot surface 11, on the basis of the imprint information and the coverage definition information 251 (S101). Thereafter, the arithmetic device 213 (pattern design circuit 222) designs the pattern P over the entire area of the shot surface 11 such that each region has a coverage falling within a coverage range set for each region (S102). The output device 214 outputs the design information including a result of the design of the pattern P to the template manufacturing apparatus 301 (S103).

As described above, according to the present embodiment, the optimized coverage range is set for each of the regions defined on the shot surface 11 in consideration of the influence of the flow of the processed layer (the uncured resist Rf in the present embodiment). This configuration makes it possible to suppress the malfunction (for example, stain or the like on the cured resist Rs after forming the pattern) due to the flow of the processed layer that may occur upon performance of the step and repeat imprint process.

Hereinafter, other embodiments will be described, but the descriptions of the same or similar portions as those of the first embodiment are appropriately omitted.

### Second Embodiment

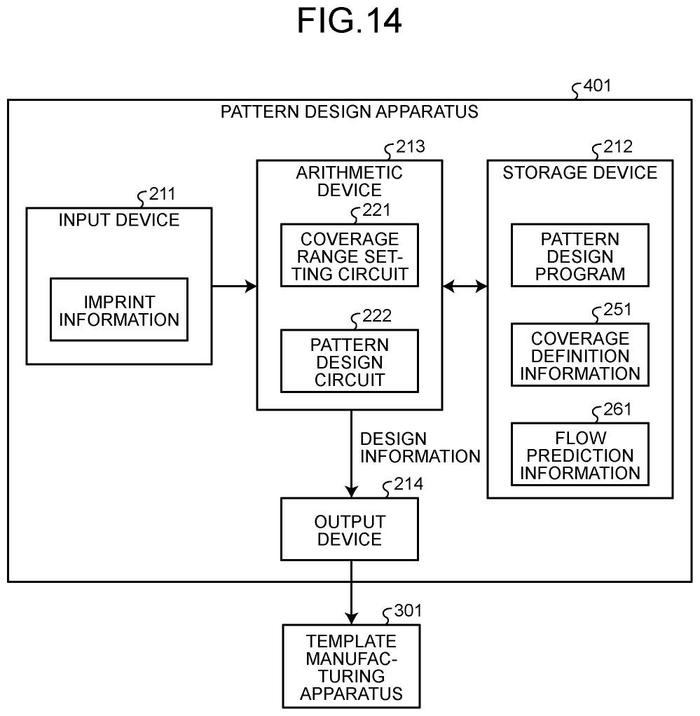

FIG. 14 is a block diagram illustrating an exemplary configuration of a pattern design apparatus 401 according to a second embodiment. The pattern design apparatus 401 of the present embodiment has a function of adjusting the position of the edge E of the shot surface 11 on the basis of prediction of the flow of the processed layer.

The storage device 212 of the present embodiment stores flow prediction information 261. The flow prediction information 261 is information representing the prediction of behavior of the processed layer (uncured resist Rf) flowing on the processed layer beyond the boundary between shot regions Sh (flowing between the shot region Sh and the boundary region B) in the imprint process using the step and repeat method. The flow prediction information 261 can include, for example, information about the viscosity, flow speed, curing rate, and the like of the resist R used as the processed layer. The flow prediction information 261 may be generated on the basis of a result of a test, simulation, or the like performed in advance, or may be, for example, sequentially generated or updated under a predetermined condition.

The pattern design circuit 222 of the arithmetic device 213 of the present embodiment adjusts a relationship between the edge of the shot surface 11, the main region Am, and the kerf region Ak, on the basis of the flow prediction information 261. The relationship is adjusted so as to prevent the main region Am from being affected by the flow of the processed layer (uncured resist Rf).

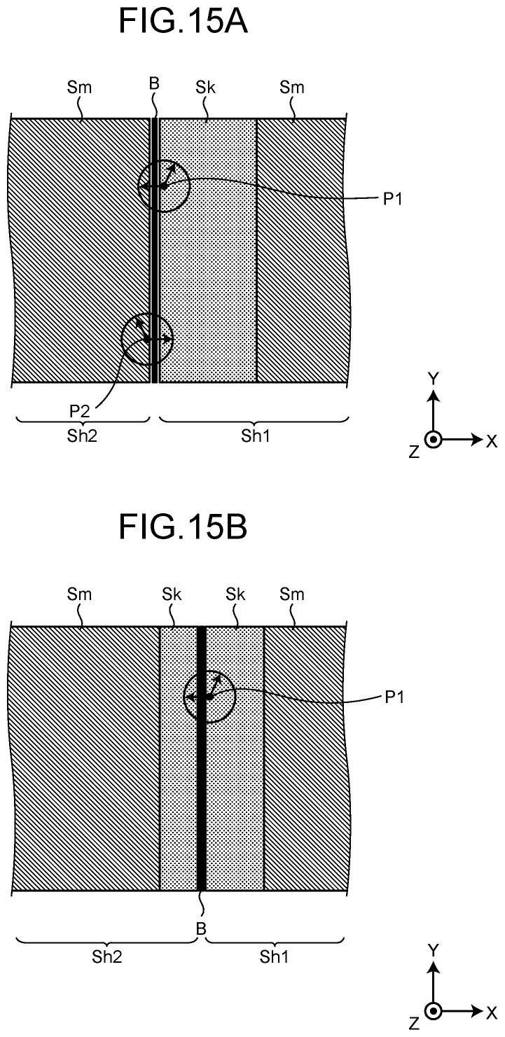

FIGS. 15A and 15B are diagrams illustrating an example of a prediction method of predicting influence of the flow of the uncured resist Rf and an example of an adjustment method of adjusting the boundary region B based on a result of the prediction, according to the second embodiment. In FIGS. 15A and 15B, the preceding shot region Sh1 and the subsequent shot region Sh2, and the boundary region B between these shot regions Sh1 and Sh2 are illustrated. In the drawing, a main shot region Sm is a region where the circuit pattern of the semiconductor device to be manufactured is formed, and is a region corresponding to the main region Am formed on the shot surface 11 of the template 10 described above. A kerf shot region Sk is a region where no circuit pattern is formed and the alignment mark or the like used in a manufacturing process for the semiconductor device is formed, finally being used as a cut region (dicing line), and is a region corresponding to the kerf region Ak formed on the shot surface 11 of the template 10 described above.

As illustrated in FIG. 15A, the pattern design circuit 222 of the present embodiment predicts the flow of the uncured resist Rf at inspection positions P1 and P2 set in the vicinity of the boundary region B, on the basis of the flow prediction information. Circles about the inspection positions P1 and P2 indicate the flow range of the uncured resist Rf. FIG. 15A illustrates a case that the main shot region Sm in the subsequent shot region Sh2 is affected by the uncured resist Rf positioned in the kerf shot region Sk in the preceding shot region Sh1.

In the above configuration, when an influence of the uncured resist Rf in the vicinity of the boundary region B on the main shot region Sm is predicted, the pattern design circuit 222 adjusts the position of the boundary region B to eliminate the influence. FIG. 15B illustrates the boundary region B after the adjustment. As illustrated in FIG. 15B, after the adjustment, the main shot region Sm is out of the range affected by the uncured resist Rf at the inspection position P1. The pattern design circuit 222 of the present embodiment adjusts a positional relationship between the edge E, the main region Am, and the kerf region Ak of the shot surface 11 of the template 10, so as to correspond to a positional relationship between the boundary region B, the main shot region Sm, and the kerf shot region Sk after the adjustment.

As described above, according to the present embodiment, the influence of the flow of the processed layer in the vicinity of the boundary between the shot regions Sh on the main shot region Sm is predicted. Then, the positional relationship between the edge E of the shot surface 11, the main region Am, and the kerf region Ak is adjusted on the basis of a result of the prediction so as to eliminate the influence. This configuration makes it possible to manufacture the template 10 that is configured to more reliably suppress the influence on the main shot region Sm.

In order to implement the function of the pattern design apparatus as described above, a computer program causing a computer (arithmetic device) to execute predetermined processing may be provided by being recorded on a computer-readable recording medium, such as a CD-ROM, a flexible disk (FD), a CD-R, or a digital versatile disk (DVD), in a file format installable or executable by the computer. Such a computer program may be configured to be stored on a computer connected to a network such as the Internet so as to be provided by being downloaded via the network. The computer program may be provided or distributed via a network such as the Internet.

While certain embodiments have been described, these embodiments have been presented by way of example only, and are not intended to limit the scope of the inventions. Indeed, the novel embodiments described herein may be embodied in a variety of other forms; moreover, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern design method to design a pattern of a template used for an imprint process, the imprint process serving to form a predetermined pattern by pressing a shot surface of the template against a surface of a processed layer, the method comprising:
setting an outer edge coverage range corresponding to a coverage range of an outer edge region located a predetermined distance inside an edge of the shot surface of the template, the outer edge coverage range being set to be different from an inner coverage range corresponding to a coverage range of an inner region inside the outer edge region;
designing a pattern in the outer edge region to have a coverage within the outer edge coverage range; and
designing a pattern in the inner region to have a coverage within the inner coverage range.

2. The pattern design method according to claim 1, wherein the outer edge coverage range is smaller than the inner coverage range.

3. The pattern design method according to claim 1, wherein an upper value of the outer edge coverage range is smaller than an upper value of the inner coverage range.

4. The pattern design method according to claim 1, wherein
the outer edge region includes
a first outer edge region located a first predetermined distance inside the edge of the shot surface, and
a second outer edge region located a second predetermined distance inside an inner edge of the first outer edge region,
the outer edge coverage range includes
a first coverage range corresponding to the first outer edge region, and
a second coverage range corresponding to the second outer edge region and being different from the first coverage range,
a pattern in the first outer edge region is designed to have a coverage within the first coverage range, and
a pattern in the second outer edge region is designed to have a coverage within the second coverage range.

5. The pattern design method according to claim 4, wherein the first coverage range is smaller than the second coverage range.

6. The pattern design method according to claim 4, wherein an upper value of the first coverage range is smaller than an upper value of the second coverage range.

7. The pattern design method according to claim 1, wherein
the shot surface includes
a preceding region located a predetermined distance inside an edge on a downstream side in a stamping direction in the imprint process performed by a step and repeat method, and
a subsequent region located a predetermined distance inside an edge on an upstream side in the stamping direction, and
the method further comprises:
setting a preceding coverage range being a coverage range corresponding to the preceding region, the preceding coverage range being set to be different from a subsequent coverage range being a coverage range corresponding to the subsequent region;
designing a pattern in the preceding region to have a coverage within the preceding coverage range; and
designing a pattern in the subsequent region to have a coverage within the subsequent coverage range.

8. The pattern design method according to claim 7, wherein the preceding coverage range is smaller than the subsequent coverage range.

9. The pattern design method according to claim 7, wherein an upper value of the preceding coverage range is smaller than an upper value of the subsequent coverage range.

10. The pattern design method according to claim 1, wherein
the shot surface includes
a main region in which a pattern is formed, and
a kerf region in which no pattern is formed, the kerf region being located around the main region, and
the method further comprises:
setting a main coverage range being a coverage range corresponding to the main region, the main coverage range being set to be different from a kerf coverage range being a coverage range corresponding to the kerf region;
designing the pattern in the main region to have a coverage within the main coverage range; and
designing a pattern in the kerf region to have a coverage within the kerf coverage range.

11. The pattern design method according to claim 10, wherein the main coverage range is smaller than the kerf coverage range.

12. The pattern design method according to claim 10, wherein an upper value of the main coverage range is smaller than an upper value of the kerf coverage range.

13. The pattern design method according to claim 10, further comprising adjusting a positional relationship between the edge of the shot surface, the main region and the kerf region, the adjusting being performed based on flow prediction information representing prediction in behavior of the processed layer flowing beyond a boundary between shot regions on the processed layer in the imprint process performed by the step and repeat method.

14. The pattern design method according to claim 1, wherein the edge of the shot surface has a jigsaw shape in a plane view.

15. A template manufacturing method to manufacture a template used for an imprint process, the imprint process serving to form a predetermined pattern by pressing a shot surface of the template against a surface of a processed layer, the method comprising:
setting an outer edge coverage range corresponding to a coverage range of an outer edge region located a predetermined distance inside an edge of the shot surface of the template, the outer edge coverage range being set to be different from an inner coverage range corresponding to a coverage range of an inner region inside the outer edge region;
generating design information including
information representing a pattern in the outer edge region designed to have a coverage within the outer edge coverage range, and
information representing a pattern in the inner region designed to have a coverage within the inner coverage range; and
forming a pattern on the shot surface based on the design information.

16. The template manufacturing method according to claim 15, wherein the outer edge coverage range is smaller than the inner coverage range.

17. The template manufacturing method according to claim 15, wherein an upper value of the outer edge coverage range is smaller than an upper value of the inner coverage range.

18. A pattern design apparatus comprising:
an arithmetic device configured to perform processing for designing a pattern of a template used for an imprint process, the imprint process serving to form a predetermined pattern by pressing a shot surface of the template against a surface of a processed layer, the processing including
setting an outer edge coverage range corresponding to a coverage range of an outer edge region located a predetermined distance inside an edge of the shot surface of the template, the outer edge coverage range being set to be different from an inner coverage range corresponding to a coverage range of an inner region inside the outer edge region,
designing a pattern in the outer edge region to have a coverage within the outer edge coverage range, and
designing a pattern in the inner region to have a coverage within the inner coverage range.

19. The pattern design apparatus according to claim 18, wherein the outer edge coverage range is smaller than the inner coverage range.

20. The pattern design apparatus according to claim 18, wherein an upper value of the outer edge coverage range is smaller than an upper value of the inner coverage range.
